(19) United States
(12) Patent Application Publication
(10) Pub. No.: US 2009/0046512 A1
(43) Pub. Date: Feb. 19, 2009

(54) Reliability System for Use with Non-Volatile Memory Devices

(76) Inventors: Munif Farhan Halloush, Round Rock, TX (US); Thomas L. Pratt, Austin, TX (US)

Correspondence Address: HAMILTON & TERRILE, LLP, P.O. BOX 203518, AUSTIN, TX, 78720, US

(21) Appl. No.: 11/840,257

(22) Filed: Aug. 17, 2007

(51) Int. Cl. G11C 11/34

(52) U.S. Cl. 365/185.09; 365/185.05

(57) ABSTRACT

A system and method which provides a non-volatile memory management system with the ability to monitor the health of a corresponding non-volatile memory and to safeguard data stored within the non-volatile memory when data integrity is at risk. The monitoring and safeguarding is provided via a crisis reliability mode module which monitors the health of a corresponding non-volatile memory and to enters a crisis reliability mode of operation when data integrity within the non-volatile memory is at risk.

### BACKGROUND OF THE INVENTION

1. Field of the Invention

The present invention relates to the field of information handling systems and more particularly to non-volatile memory used with information handing systems.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to store data on an information handling system using non-volatile memory such as flash memory. Flash memory is an example of non-volatile computer memory that can be electrically erased and reprogrammed. Flash memory generally includes a plurality of blocks, where each block is divided into a plurality of pages. Each page includes a data portion as well as a system portion. User data is stored within the data portion. System information, including error correction code (ECC) information as well as overhead information, are stored within the system portion. The flash memory also includes spare sections which can be used when sections within the data portion are inoperable. Remapping to these spare sections is part of what is referred to as bad block management. FIG. 1, labeled Prior Art, shows a block diagram of a typical flash memory architecture.

One issue relating to flash memory is that flash memory has limited erase/program cycles. This limit is characterized by the inability to reliably write data to the memory cells and is generally related to the number of times a cell is erased and programmed. For this reason, flash management systems (e.g., flash memory controllers) typically perform wear leveling operations of data across the address space of the flash memory. With a wear leveling operation, no portion of the flash memory receives an inordinately high number of erase and program cycles compared to other portions of the flash memory. Thus, wear leveling can maximize the erase/program life of the device as a whole.

Wear leveling operations are usually performed by abstracting the data logical block addresses (LBAs) within the flash memory's physical memory area. There are many known methods for performing wear leveling operations, some of which are more effective than others. Another issue relating to flash memory is that as the flash device reaches the limits of its erase and program cycle lifetime, it is difficult to ensure the integrity of user data stored on the flash memory.

Accordingly, it would be desirable to provide a flash memory management system with the ability to monitor the health of a corresponding flash memory and to safeguard data stored within the flash memory when data integrity is at risk.

### SUMMARY OF THE INVENTION

In accordance with the present invention, a system and method is disclosed which provides a flash memory management system with the ability to monitor the health of a corresponding flash memory and to safeguard data stored within the flash memory when data integrity is at risk. The monitoring and safeguarding is provided via a crisis reliability mode module which monitors the health of a corresponding flash memory and to enters a crisis reliability mode of operation when data integrity within the flash memory is at risk.

The crisis reliability mode of operation is declared when the memory management system determines that it may not guarantee the data integrity of data stored within a corresponding flash memory. Data integrity may be at risk for such reasons as a low number of reserved spare blocks, a high number of erase and program cycles that may exceed or approach a device's capability or a high level of error correction code (ECC) correction of data or error detection code (EDC) detected errors for data that is read from the flash memory.

In certain embodiments, the crisis reliability mode module monitors any of these conditions and, if true, causes the device to enter a crisis reliability mode of operation. During the crisis reliability mode of operation, the device scans for available user data blocks that can be used as extra spare blocks and then sets a flag for an LBA counter change. The LBA counter change flag initiates the process of reallocation of blocks for the next device power on cycle. Thus during the next power on cycle, the device reduces the user data space within the flash memory device and increases the spare block space. After the device has been restored to a healthy level of spare blocks, the flash memory management system returns to a normal operational mode with low risk to data integrity. The reliability improvement module can be implemented within software so that no change to device hardware is necessary.

In one embodiment, the invention relates to a method for ensuring data integrity within a flash memory which includes monitoring flash memory operations to determine whether a crisis reliability mode condition is present, and operating the flash memory in a crisis reliability mode of operation when a crisis reliability mode condition is present.

In another embodiment, the invention relates to a system for ensuring data integrity within a flash memory which includes means for monitoring flash memory operations to determine whether a crisis reliability mode condition is present, and means for operating the flash memory in a crisis reliability mode of operation when a crisis reliability mode condition is present.

In another embodiment, the invention relates to an information handing system which includes a processor and memory coupled to the processor. The memory stores a module for ensuring data integrity within a flash memory. The module is executable by the processor for monitoring flash memory operations to determine whether a crisis reliability mode condition is present, and operating the flash memory in a crisis reliability mode of operation when a crisis reliability mode condition is present.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1, labeled Prior Art, shows a block diagram of a typical flash memory architecture.

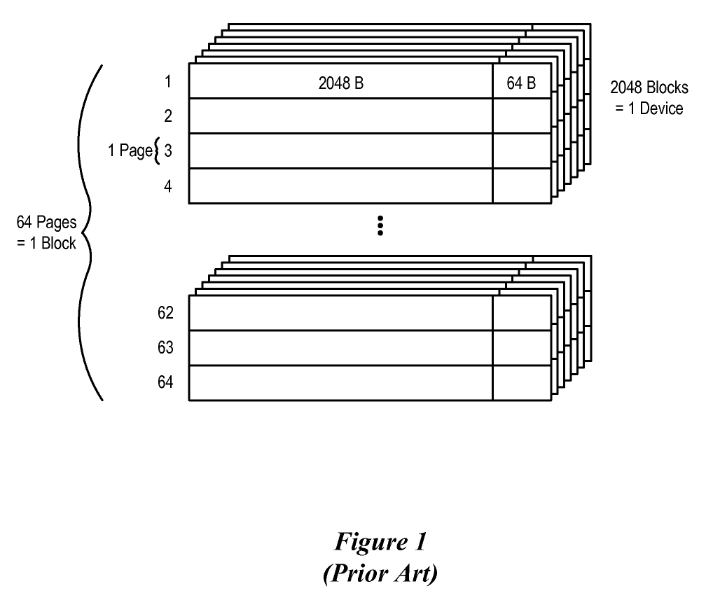

FIG. 2 shows a block diagram of an information handing system which includes a flash memory management system in accordance with the present invention.

FIG. 3 shows a flow chart of the operation of a system for ensuring data integrity within a flash memory.

### DETAILED DESCRIPTION

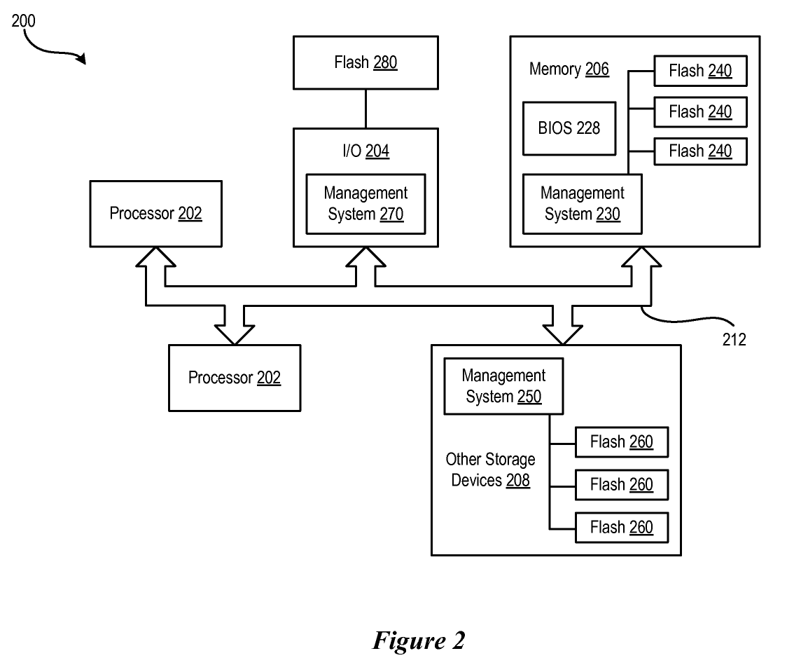

FIG. 2 shows a block diagram of an information handing system 200 which includes a flash memory management system in accordance with the present invention. The information handling system 200 includes a processor 202, input/output (I/O) devices 204, such as a display, a keyboard, a mouse, and associated controllers, memory 206 including non-volatile memory such as a hard disk drive and volatile memory such as random access memory, and other storage devices 208, such as an optical disk and drive and other memory devices, and various other subsystems 210, all interconnected via one or more buses, shown collectively as bus 212. The memory 206 includes a basic input output system 228 which is executed by the processor.

The information handing system also includes one or more flash memory devices and corresponding flash memory management systems. For example, the memory 206 can include a flash memory management system 230 as well as one or more flash memory modules 240. The other storage devices 208 can include a flash memory management system 250 as well as one or more flash memory modules 260. Additionally, the I/O devices 204 can include a connector (such as a USB connector) via which a flash memory can be coupled to the information handling system. Thus, the I/O devices 204 can include a flash memory management system 270 which controls access to a flash memory module 280.

Each of the flash memory management systems 230, 250, 270 includes a crisis reliability mode module which enables the memory management system to monitor the health of a corresponding flash memory and to enter a crisis reliability mode of operation when data integrity within the flash memory is at risk.

The crisis reliability mode of operation is declared when the memory management system determines that it may not guarantee the data integrity of data stored within a corresponding flash memory. Data integrity may be at risk for such reasons as a low number of reserved spare blocks, a high number of erase and program cycles that may exceed or approach a device's capability or a high level of error correction code (ECC) correction of data or EDC detected errors for data that is read from the flash memory.

The crisis reliability mode module monitors any of these conditions and, if true, causes the device to enter a crisis reliability mode of operation. During the crisis reliability mode of operation, the device scans for available user data blocks that can be used as extra spare blocks and then sets a flag for an LBA counter change. The LBA counter change flag initiates the process of reallocation of blocks for the next device power on cycle. Thus during the next power on cycle, the device reduces the user data space within the flash memory device and increases the spare block space. After the device has been restored to a healthy level of spare blocks, the flash memory management system returns to a normal operational mode with low risk to data integrity. The reliability improvement module can be implemented within software so that no change to device hardware is necessary.

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

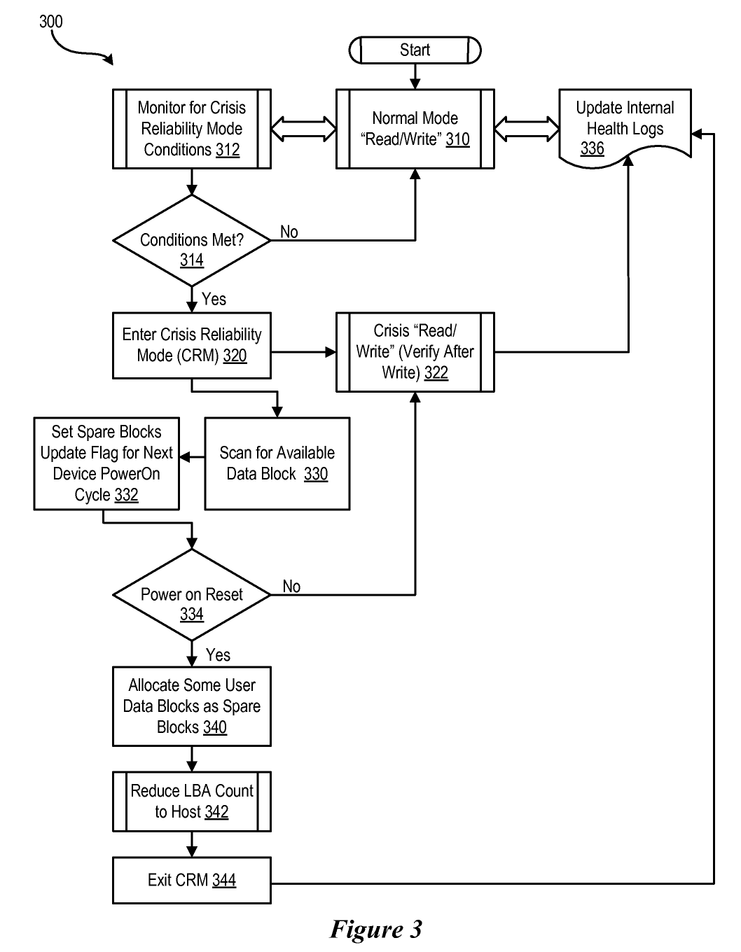

FIG. 3 shows a flow chart of the operation of a system for ensuring data integrity within a flash memory. More specifically, during a normal mode of operation of the flash memory device at step 310, the system 300 monitors for crisis reliability mode conditions at step 312. If none of the crisis reliability mode conditions are met as determined by step 314, then the system 300 returns to the normal mode of operation at step 310. Crisis reliability mode conditions include, for example, whether a number of available reserved spare blocks is below a predetermined threshold (the predetermined threshold relates to whether there are enough spare blocks left to replace blocks within the data portion of the memory that are not functioning properly), whether a number of erase and program cycles exceed a predetermined threshold (the predetermined threshold relates to whether the number of erase and program cycles exceed or approach a device's capability) or whether a high level of error correction code (ECC) correction or EDC detected errors for data that is read from the flash memory is occurring (the high level of ECC correction or EDC detected errors may indicate that bits within the data portion are failing).

If any of the crisis reliability mode conditions are met, then the system 300 enters a crisis reliability mode of operation at step 320. During the crisis reliability mode of operation the system 300 performs a crisis read write operation at step 322 where a verify after write operation is performed for each write to the flash memory. Also, during the crisis reliability mode of operation, the system 300 scans the data portion of the flash memory for spare blocks at step 330 and sets spare blocks with an update flag at step 332. The update flag indicates that for the next device power on cycle, the identified block will be configured as a spare block. Next, the system determines whether a power on reset operation is performed at step 334. If a power on reset operation is not performed, then the system 300 continues to perform the crisis read write operation at step 322. After the crisis read write operation is performed at step 332, the internal health logs of the memory device are updated at step 336.

When a power on reset operation occurs, as determined by step 334, then the system 300 allocates user data blocks within the memory as spare blocks at step 340. Next at step 342 the system 300 reduces the LBA count that is provided to the host (e.g., the processor executing BIOS 228). Reducing the LBA count causes the size of available flash memory to be smaller by the amount of data blocks that were reallocated as spare blocks. After the LBA count is reduced, the system 300 exits the crisis reliability mode of operation at step 344 and updates the internal health logs of the memory device at step 336. In certain embodiments, a system reset is used after the size of the flash memory is changed because the operating system executing on the information handing system could lock up or generate an error condition if the size of the flash memory (e.g., as indicated by the LBA count) does not correspond to the size expected by the operating system.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

For example, while the information handling system is shown with separate flash memory management systems for each type of flash memory device, it will be appreciated that other configurations of flash memory management systems (e.g., a single flash memory management system or other multiples of flash memory management systems) are within the scope of the invention.

Also for example, while flash memory is shown as an example of non-volatile memory, it will be appreciated that other types of non-volatile memory having limited program cycles are within the scope of the invention.

Also for example, it will be appreciated that some or all of the flash memory management system or controllers can be instantiated by instructions executing on a processor such as the processor 202 or within hardware such as an application specific integrated circuit (ASIC) or within a combination of instructions and hardware. Also, for example, it will be appreciated that the system for ensuring data integrity can be instantiated by instructions executing on a processor such as the processor 202 or within hardware such as an application specific integrated circuit (ASIC) or within a combination of instructions and hardware.

Also for example, it will be appreciated that while certain conditions are set forth that indicate that entry into the crisis reliability mode of operation is desirable, other types of conditions are within the scope of the invention.

Also, for example, the above-discussed embodiments include software modules that perform certain tasks. The software modules discussed herein may include script, batch, or other executable files. The software modules may be stored on a machine-readable or computer-readable storage medium such as a disk drive. Storage devices used for storing software modules in accordance with an embodiment of the invention may be magnetic floppy disks, hard disks, or optical discs such as CD-ROMs or CD-Rs, for example. A storage device used for storing firmware or hardware modules in accordance with an embodiment of the invention may also include a semiconductor-based memory, which may be permanently, removably or remotely coupled to a microprocessor/memory system. Thus, the modules may be stored within a computer system memory to configure the computer system to perform the functions of the module. Other new and various types of computer-readable storage media may be used to store the modules discussed herein. Additionally, those skilled in the art will recognize that the separation of functionality into modules is for illustrative purposes. Alternative embodiments may merge the functionality of multiple modules into a single module or may impose an alternate decomposition of functionality of modules. For example, a software module for calling sub-modules may be decomposed so that each sub-module performs its function and passes control directly to another sub-module.

Consequently, the invention is intended to be limited only by the spirit and scope of the appended claims, giving full cognizance to equivalents in all respects.

What is claimed is:

1. A method for ensuring data integrity within a non-volatile memory having finite program cycles comprising:
monitoring memory operations to determine whether a crisis reliability mode condition is present;
operating the non-volatile memory in a crisis reliability mode of operation when a crisis reliability mode condition is present.

2. The method of claim 1 wherein the crisis reliability mode of operation further comprises:
performing a verify after write operation for every write operation that is performed on the non-volatile memory.

3. The method of claim 1 wherein the crisis reliability mode of operation further comprises:
scanning the data portion of the non-volatile memory to identify available blocks;
identifying the available blocks as potential spare blocks.

4. The method of claim 3 wherein the crisis reliability mode of operation further comprises:
allocating at least one of the available blocks as spare blocks; and,
reducing a logical block address for the non-volatile memory to correspond to a reduced memory size, an amount of reduction in memory size corresponding to a number of available blocks allocated as spare blocks.

5. The method of claim 1 wherein the crisis reliability mode condition comprises:
whether a number of available reserved spare blocks is below a predetermined threshold, the predetermined threshold relating to whether there are enough spare blocks left to replace blocks within a data portion of the non-volatile memory.

6. The method of claim 1 wherein the crisis reliability mode condition comprises:
whether a number of erase and program cycles performed on the non-volatile memory exceed a predetermined threshold, the predetermined threshold relating to whether the number of erase and program cycles approach a cycle capacity of the non-volatile memory.

7. The method of claim 1 wherein the crisis reliability mode condition comprises:
whether a high level of error correction code (ECC) correction or error detection code (EDC) detected errors for data read from the non-volatile memory has occurred.

8. A system for ensuring data integrity within a non-volatile memory comprising:
means for monitoring memory operations to determine whether a crisis reliability mode condition is present; and,
means for operating the non-volatile memory in a crisis reliability mode of operation when a crisis reliability mode condition is present.

9. The system of claim 8 wherein the means for operating the non-volatile memory in a crisis reliability mode of operation further comprises:
means for performing a verify after write operation for every write operation that is performed on the non-volatile memory.

10. The system of claim 8 wherein the means for operating the non-volatile memory in a crisis reliability mode of operation further comprises:
means for scanning the data portion of the non-volatile memory to identify available blocks; and,
means for identifying the available blocks as potential spare blocks.

11. The system of claim 10 wherein the means for operating the non-volatile memory in a crisis reliability mode of operation further comprises:
means for allocating at least one of the available blocks as spare blocks; and,
means for reducing a logical block address for the non-volatile memory to correspond to a reduced memory size, an amount of reduction in memory size corresponding to a number of available blocks allocated as spare blocks.

12. The system of claim 8 wherein the crisis reliability mode condition comprises:
whether a number of available reserved spare blocks is below a predetermined threshold, the predetermined threshold relating to whether there are enough spare blocks left to replace blocks within a data portion of the non-volatile memory.

13. The system of claim 8 wherein the crisis reliability mode condition comprises:
whether a number of erase and program cycles performed on the non-volatile memory exceed a predetermined threshold, the predetermined threshold relating to whether the number of erase and program cycles approach a erase and program cycle capacity of the non-volatile memory.

14. The system of claim 8 wherein the crisis reliability mode condition comprises:
whether a high level of error correction code (ECC) correction or error detection code (EDC) detected errors for data read from the non-volatile memory has occurred.

15. An information handing system comprising
a processor;
memory coupled to the processor, the memory storing a module for ensuring data integrity within a non-volatile memory, the module comprising executable by the processor for:
monitoring memory operations to determine whether a crisis reliability mode condition is present;
operating the non-volatile memory in a crisis reliability mode of operation when a crisis reliability mode condition is present.

16. The information handing system of claim 15 wherein the module further comprises instructions for:
performing a verify after write operation for every write operation that is performed on the non-volatile memory.

17. The information handing system of claim 15 wherein the module further comprises instructions for:
scanning the data portion of the non-volatile memory to identify available blocks;
identifying the available blocks as potential spare blocks.

18. The information handing system of claim 17 wherein the module further comprises instructions for:
allocating at least one of the available blocks as spare blocks; and,
reducing a logical block address for the non-volatile memory to correspond to a reduced memory size, an amount of reduction in memory size corresponding to a number of available blocks allocated as spare blocks.

19. The information handing system of claim 15 wherein the crisis reliability mode condition comprises:
whether a number of available reserved spare blocks is below a predetermined threshold, the predetermined threshold relating to whether there are enough spare blocks left to replace blocks within a data portion of the non-volatile memory.

20. The information handing system of claim 15 wherein the crisis reliability mode condition comprises:
whether a number of erase and program cycles performed on the non-volatile memory exceed a predetermined threshold, the predetermined threshold relating to whether the number of erase and program cycles approach a erase and program cycle capacity of the non-volatile memory.

21. The information handing system of claim 15 wherein the crisis reliability mode condition comprises:
whether a high level of error correction code (ECC) correction or error detection code (EDC) detected errors for data read from the non-volatile memory has occurred.
